(19) United States
(12) Patent Application Publication
(10) Pub. No.: US 2015/0062422 A1
(43) Pub. Date: Mar. 5, 2015

(54) LENS ALIGNMENT IN CAMERA MODULES USING PHASE DETECTION PIXELS

(71) Applicant: SEMICONDUCTOR COMPONENTS INDUSTRIES, LLC, Phoenix, AZ (US)

(72) Inventor: Jonathan Michael Stern, San Carlos, CA (US)

(73) Assignee: SEMICONDUCTOR COMPONENTS INDUSTRIES, LLC, Phoenix, AZ (US)

(21) Appl. No.: 14/470,862

(22) Filed: Aug. 27, 2014

Related U.S. Application Data
(60) Provisional application No. 61/870,453, filed on Aug. 27, 2013.

(51) Int. Cl. H04N 5/225

(52) U.S. Cl. CPC H04N 5/2254
USPC 348/374

(57) ABSTRACT

Image sensors may include image pixels and phase detection pixels. Phase detection pixels may he used during active lens alignment operations to accurately align camera module optics to the image sensor during camera module assembly. During active alignment operations, phase detection pixels may gather phase information from a target that is viewed through the camera module optics. Control circuitry may process the phase information to determine a distance and direction of lens movement needed to bring the target into focus and thereby align the camera module optics to the image sensor. A computer-controlled positioner may be used to adjust a position of the camera module optics relative to the image sensor based on information from the phase detection pixels. Once the camera module optics are accurately aligned relative to the image sensor, structures in the camera module assembly may be permanently attached to lock the alignment in place.

This application claims the benefit of provisional patent application No. 61/870,453, filed Aug. 27, 2013, which is hereby incorporated by reference herein in its entirety.

### BACKGROUND

This relates generally to imaging systems and more particularly, to aligning camera optics in a camera module with respect to an image sensor in the camera module.

Modern electronic devices such as cellular telephones, cameras, and computers often include camera modules having digital image sensors. An image sensor (sometimes referred to as an imager) may be formed from a two-dimensional array of image sensing pixels. Each pixel receives incident photons (light) and converts the photons into electrical signals.

Camera module assembly typically requires a lens focusing step. Lens focusing can be performed manually or can be performed using an automatic active alignment system. In active alignment operations, the image sensor is active and operational during the alignment process. A calibration target is viewed through the camera optics and captured using the image sensor.

In conventional active alignment systems, contrast detection algorithms are used in conjunction with a multi-axis manipulator to move the lens until it is accurately aligned with respect to the image sensor. Using the contrast detection method, the contrast of the image is measured using contrast detection, algorithms that provide a measure of edge contrast. Higher edge contrast corresponds to better focus. Thus, the objective of the contrast detection method is to determine the lens position that maximizes contrast. The process involves making small changes in the lens position, capturing an image of a target through the lens, reading out the image, determining a contrast of the image, and determining whether and by how much focus has improved with respect to the last lens position. Based on this information, the lens position is adjusted to a new focusing distance and the process is repeated until to relative maximum in edge contrast is determined. When the lens is accurately aligned with respect to the image sensor, the lens is locked in place.

The contrast detection method of active alignment is inherently a slow trial and error process and significantly contributes to the production cycle time of the active alignment assembly process.

It would therefore be desirable to provide improved ways of aligning camera optics to an image sensor during the camera module assembly process.

### BRIEF DESCRIPTION OF THE DRAWINGS

FIG. 1 is a schematic diagram of an illustrative electronic device with an image sensor having phase detection pixels that may be used in an active alignment process in accordance with an embodiment of the present invention.

FIG. 2A is a cross-sectional view of illustrative phase detection pixels having photosensitive regions with different and asymmetric angular responses in accordance with an embodiment of the present invention.

FIGS. 2B and 2C are cross-sectional views of the phase detection pixels of FIG. 2A in accordance with an embodiment of the present invention.

FIG. 3 is a diagram of illustrative signal outputs of phase detection pixels for incident light striking the phase detection pixels at varying angles of incidence in accordance with an embodiment of the present invention.

FIG. 4A is a top view of an illustrative phase detection pixel pair arranged horizontally in accordance with an embed invent of the present invention.

FIG. 4B is a top view of an illustrative phase detection pixel pair arranged vertically in accordance with an embodiment of the present invention.

FIG. 4C is a top view of an illustrative phase detection pixel pair arranged vertically and configured to detect phase differences along the horizontal direction in accordance with an embodiment of the present invention.

FIG. 5 is a diagram of an illustrative active lens alignment system that uses phase detection pixels in an image sensor to align camera optics to the image sensor during assembly operations in accordance with an embodiment of the present invention.

FIG. 6 is cross-sectional side view of an illustrative camera module in which a lens is aligned with respect to a housing in accordance with an embodiment of the present invention.

FIG. 7 is a cross-sectional side view of an illustrative camera module in which a lens and housing are aligned with respect to a printed circuit substrate in accordance with an embodiment of the present invention.

FIG. 8 is a cross-sectional side view of an illustrative camera module in which an upper assembly including a lens and an actuated focusing system is aligned with respect to a lower assembly including an image sensor in accordance with an embodiment of the present invention.

FIG. 9 is a cross-sectional side view of an illustrative camera module in which an upper assembly including a lens and an actuated focusing system is fixed to an enclosure and aligned with respect to substrate on which an image sensor is mounted in accordance with an embodiment of the present invention.

FIG. 10 is a flow chart of illustrative steps involved in aligning camera optics to an image sensor using phase detection pixels in the image sensor in accordance with an embodiment of the present invention.

### DETAILED DESCRIPTION

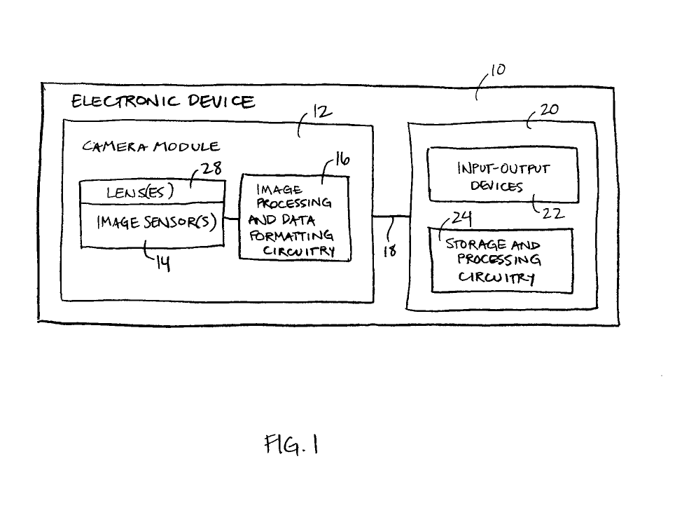

Embodiments of the present invention relate to image Sensors ha me phase detection pixels that ma be used during camera module assembly for active lens alignment. The phase detection pixels may also be used during image capture operations to provide automatic focusing and depth sensing functionality. An electronic device with a camera module is shown in FIG. 1. Electronic device 10 ma be a digital camera, a computer, a cellular telephone, a medical device, or other electronic device. Camera module 1 (sometimes referred to as an imaging device) may include one or more image sensors 14 and one or more tenses 28. During operation, lenses 28 (sometimes referred to as optics 28 or optical elements 28) focus light onto image sensor 14. Image sensor 14 includes photosensitive elements (e.g., pixels) that convert the light into digital data. Image sensors may have any number of pixels (e.g., hundreds, thousands, millions, or more). A typical image sensor May for example have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 14 may be provided to image processing and data formatting circuitry 16. Image processing and data formatting circuitry 16 may be used to perform image processing functions such as automatic focusing functions, depth sensing data formatting, adjusting white balance and exposure, implementing video image stabilization, face detection, etc. For example, during automatic focusing operations, image processing and data formatting circuitry 16 may process data gathered by phase detection pixels in image sensor 14 to determine the magnitude and direction of lens movement (e.g., movement of lens 28) needed to bring an object of interest into focus.

Image processing and data formatting circuitry 16 may also he used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common integrated circuit. The use of a single integrated circuit to implement camera sensor 14 and image processing and data formatting circuitry 16 can help to reduce costs. This is, however, merely illustrative. If desired, camera sensor 14 and image processing and data formatting circuitry 16 may be implemented using separate integrated circuits.

Camera module 12 may convey acquired image data to host subsystems 20 over path 18 (e.g., image processing and data formatting circuitry 16 may convey image data to subsystems 20). Electronic device 10 typically provides a user with numerous high-level functions. in a computer or advanced cellular telephone, for example, a user may be provided with the ability to run user applications. To implement these functions. host subsystem 20 of electronic device 10 may include storage and processing circuitry 24 and input-output devices 22 such as keypads, input-output ports, joysticks, and displays. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits or other processing circuits.

Image sensor 14 may include phase detection pixels for determining whether an image is in focus. Phase detection pixels in image sensor 14 may be used for automatic focusing operations, depth sensing functions, and/or 3D imaging applications. Phase detection pixels may also be used during camera mod le assembly operations to align the camera optics to the image sensor (e.g., to align lens 28 to image sensor 14).

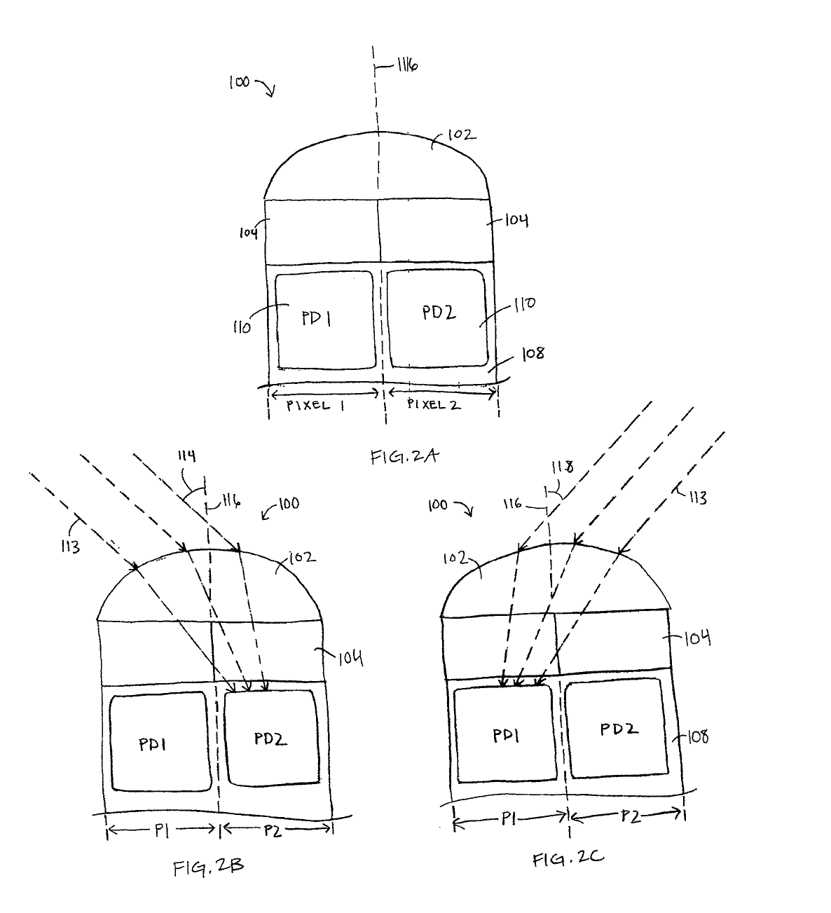

Phase detection pixels may be used in groups such as pixel pair 100 shown in FIG. 2A. FIG. 2A is a cross-sectional side view of an illustrative pixel pair 100. Pixel pair 100 may include first and second pixels such Pixel 1 and Pixel 2, Pixel 1 and Pixel 2 may include photosensitive regions 110 formed in a substrate such as silicon substrate 108. For example, Pixel 1 may include an associated photosensitive region such as photodiode PD1 and Pixel 2 may include an associated photosensitive region such as photodiode PD2. A microlens may he formed over photodiodes PD1 and PD2 and may be used to direct incident light towards photodiodes PD1 and PD2. The arrangement of FIG. 2A in which microlens 102 covers two pixel regions may sometimes be referred to as a 2×1 or 1×2 arrangement because there are two phase detection pixels arranged consecutively in a line.

Color filters such as color filter elements 104 may be interposed between microlens 102 and substrate 108. Color filter elements 104 may filter incident light by only allowing predetermined wavelengths to pass through color filter elements 104 (e.g., color filter 104 may only be transparent to the certain ranges of wavelengths). Photodiodes PD1 and PD2 may serve to absorb incident light focused by microlens 102 and produce pixel signals that correspond to the amount of incident light absorbed.

Photodiodes PD1 and PD2 may each cover approximately half of the substrate area under microlens 102 (as an example). By only covering half of the substrate area, each photosensitive region may be provided with an asymmetric angular response (e.g., photodiode PD1 may produce different image signals based on the angle at which incident light reaches pixel pair 100). The angle at which incident light reaches pixel pair 100 relative to a normal axis 116 (i.e., the angle at which incident light strikes microlens 102 relative to the optical axis 116 of lens 102) may be herein referred to as the incident angle or angle of incidence.

An image sensor can be formed using front side illumination imager arrangements (e.g., where circuitry such as metal interconnect circuitry is interposed between the microlens array and the photosensitive regions) or backside illumination imager arrangements (e.g., where the photosensitive regions are interposed between the microlens array and the metal interconnect circuitry). The example of FIGS. 2A, 2B, and 2C in which pixels 1 and 2 are backside illuminated image sensor pixels is merely illustrative. If desired, pixels 1 and 2 may he front side illuminated image sensor pixels. Arrangements in which pixels are backside illuminated image sensor pixels are sometimes described herein as an example.

In the example of FIG. 2B, incident light 113 may originate from the left of normal axis 116 and may reach pixel pair 100 with an angle 114 relative to normal axis 116. Angle 114 may be a negative angle of incident light. Incident light 113 that reaches microlens 102 at a negative angle such as angle 114 may be focused towards photodiode PD2. In this scenario, photodiode PD2 may produce relatively high image signals, whereas photodiode PD1 may produce relatively low image signals (e.g., because incident light 113 is not focused towards photodiode PD1).

In the example of FIG. 2C, incident light 113 may originate from the right of normal axis 116 and reach pixel pair 100 with an angle 118 relative to normal axis 116. Angle 118 may be a positive angle of incident light. Incident light that reaches microlens 102 at a positive angle such as angle 118 may be focused towards photodiode PD1 (e.g., the light is not focused towards photodiode PD2). In this scenario, photodiode PD2 may produce an image signal output that is relatively low, whereas photodiode PD1 may produce an image signal output that is relatively high.

The positions of photodiodes PD1 and PD2 may sometimes be referred to as asymmetric, positions because the center of each photosensitive area 110 is offset from (i.e., not aligned with) optical axis 116 of microlens 102. Due to the asymmetric formation of individual photodiodes PD1 and PD2 in substrate 108, each photosensitive area 110 ma have an asymmetric angular response (e.g., the signal output produced by each photodiode 110 in response to incident light with a given intensity may vary based on an angle of incidence). In the diagram of FIG. 3, an example of the pixel signal outputs of photodiodes PD1 and PD2 of pixel pair 100 in response to varying angles of incident light is shown.

Line 160 may represent the output image signal for photodiode PD2 whereas line 162 may represent the output image signal for photodiode PD1. For negative angles of incidence. the output image signal for photodiode PD2 may increase (e.g., because incident light is focused onto photodiode PD2) and the output image signal for photodiode PD1 may decrease (e.g., because incident light is focused away from photodiode PD1). For positive angles of incidence, the output image signal for photodiode PD2 may be relatively small and the output image signal for photodiode PD1 may be relatively large.

The size and location of photodiodes PD1 and PD2 of pixel pair 100 of FIGS. 2A, 2B, and 2C are merely illustrative. If desired, the edges of photodiodes PD1 and PD2 may be located at the center of pixel pair 100 or may be shifted slightly away from the center of pixel pair 100 in any direction. If desired, photodiodes 110 may be decreased in size to cover less than half of the pixel area.

Output signals from pixel pairs such as pixel pair 100 may be used to adjust the optics (e.g., one or more lenses such as lenses 28 of FIG. 1) in image sensor 14 during camera module assembly (e.g., during manufacturing). If desired, phase detection pixels 100 may also be used during automatic focusing operations (e.g., when camera module 12 is being operated by a user). The direction and magnitude of lens movement needed to bring an object of interest into focus may be determined based on the output signals from pixel pairs 100.

When an object is in focus, light from both sides of the image sensor optics converges to create a focused image. When an object is out of focus, the images projected by two sides of the optics do not overlap because they are out of phase with one another. By creating pairs of pixels where each pixel is sensitive to light from one side of the lens or the other a phase difference can be determined. This phase difference can be used to determine the direction and magnitude of optics movement needed to bring the images into phase and thereby focus the object of interest. Pixel groups that are used to determine phase difference information such as pixel pair 100 are sometimes referred to herein as phase detection pixels or depth-sensing pixels.

A phase difference signal may be calculated by comparing the output pixel signal of PD1 with that of PD2. For example, a phase difference signal for pixel pair 100 may be determined by subtracting the pixel signal output of PD1 from the pixel signal output of PD2 (e.g., by subtracting line 162 from line 160). For an object at a distance that is less than the focused object distance, the phase difference signal may be negative. For an object at a distance that is greater than the focused object distance, the phase difference signal may be positive. This information may he used to automatically adjust the image sensor optics to bring the object of interest into focus (e.g., by bringing the pixel signals into phase with one another).

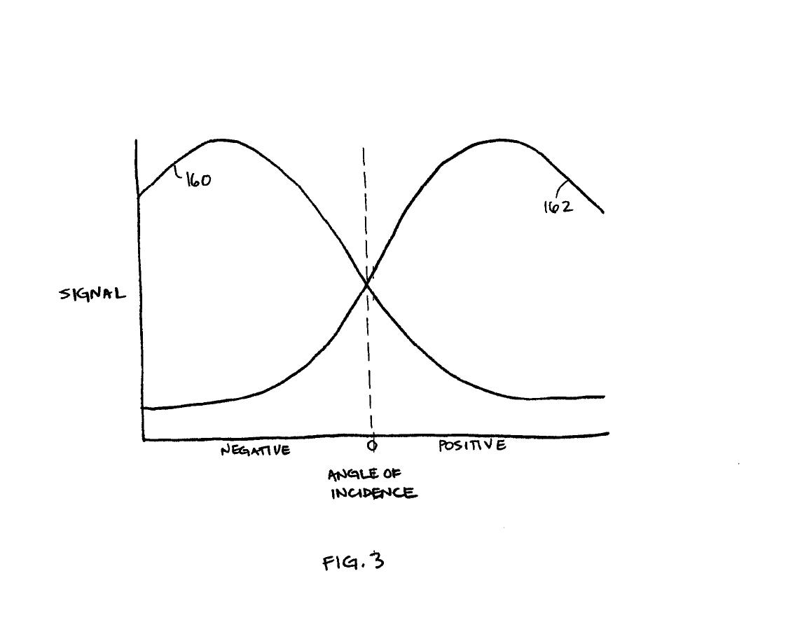

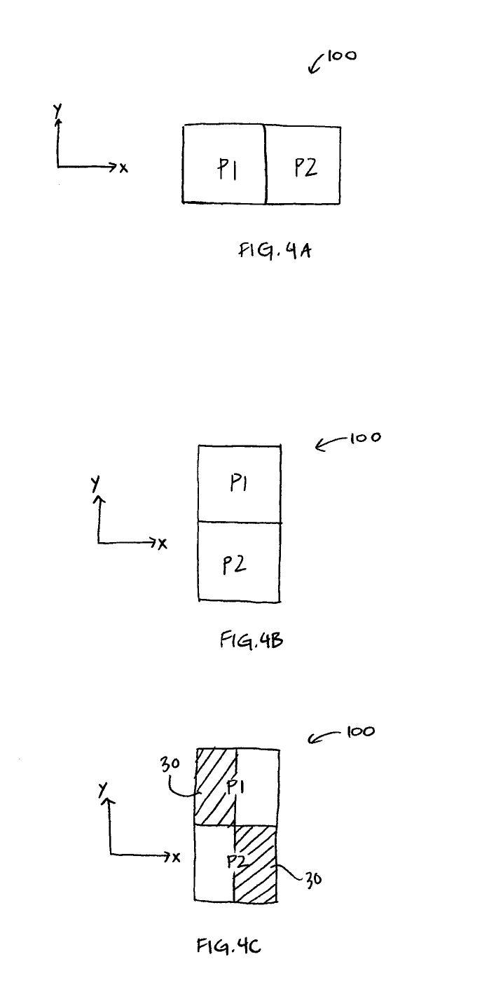

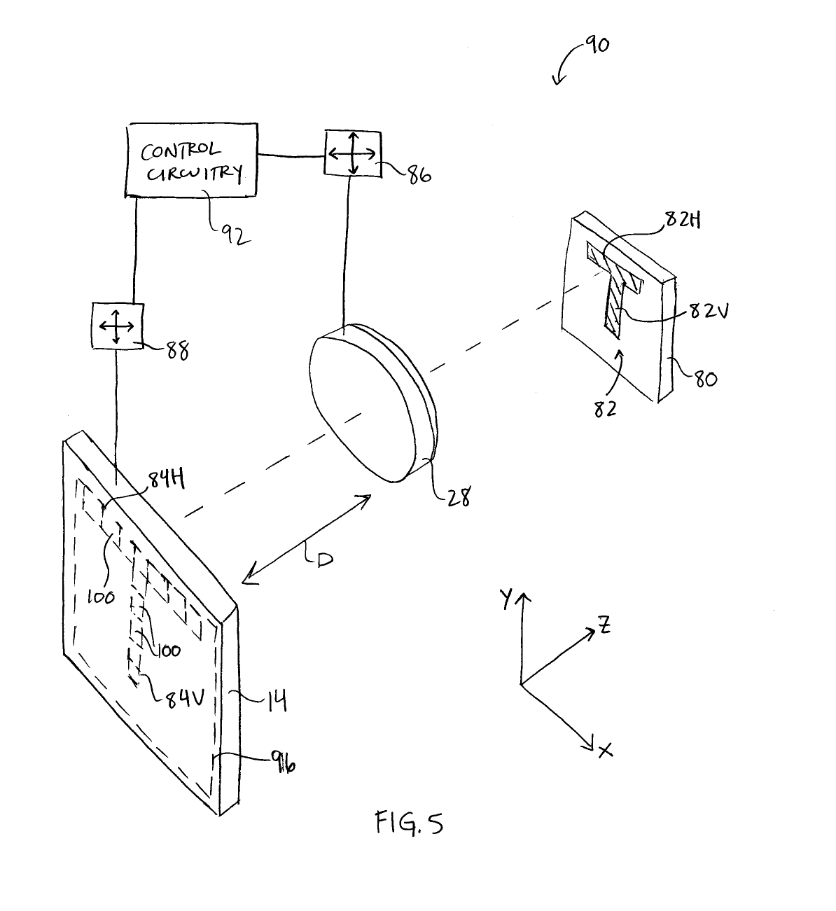

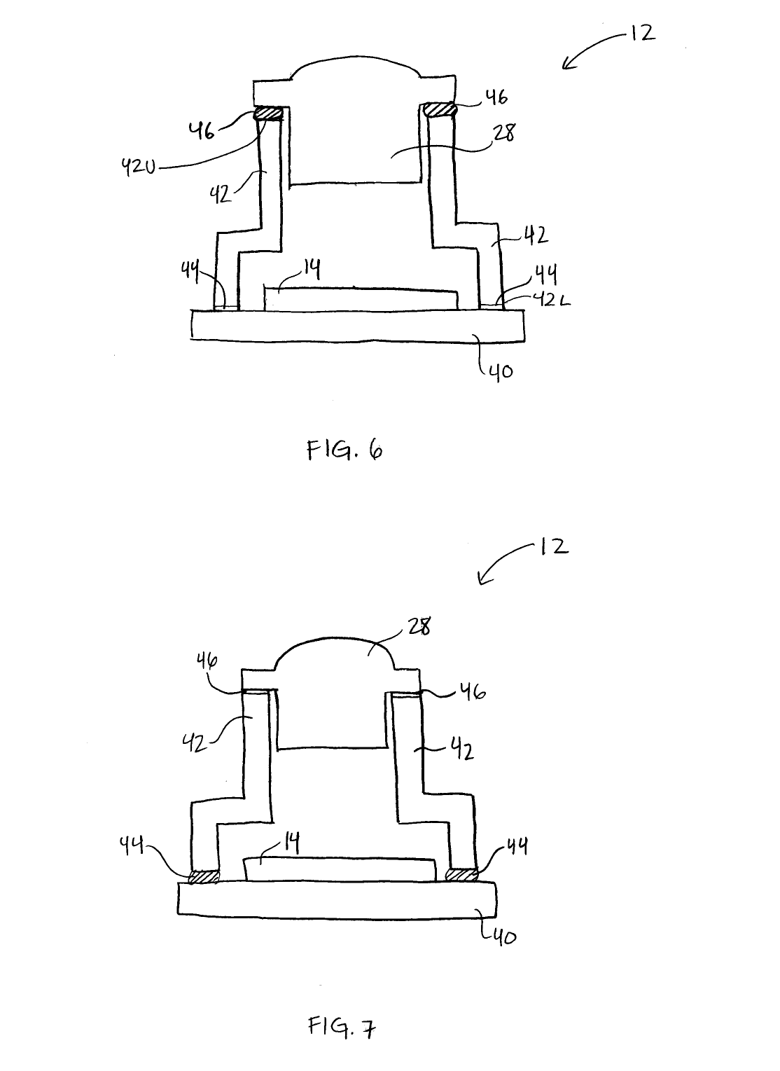

Pixel pairs 100 may arranged in various ways. For example, as shown in FIG. 4A. Pixel 1 (referred to herein as P1) and Pixel 2 (referred to herein is P2) of pixel pair 100 may he oriented horizontally, parallel to the x-axis of FIG. 4A (e.g., may be located in the same row of a pixel array). In the example of FIG. 4B, P1 and P2 are oriented vertically, parallel to the y-axis of FIG. 4B (e.g., in the same column of a pixel array). In the example of FIG. 4C, P1 and P2 are arranged vertically and are configured to detect phase differences in the horizontal direction (e.g., using an opaque light shielding layer such as metal mask 30). Various arrangements for phase detection pixels are described in detail in U.S. patent application Ser. No. 14/267,695, filed May 1, 2014, which is hereby incorporated by reference herein in its entirety.

Phase detection pixels such as phase detection pixels 100 in image sensor 14 may be used during camera module assembly operations to align camera optics such as lens 28 with respect to image sensor 14. For example, prior to permanently attaching lens 28 or a housing that supports lens 28 within the camera module assembly, phase detection pixels 100 in image sensor 14 may be used during an active alignment process to determine the accurate position of lens 28 with respect to image sensor 14.

A diagram illustrating an active alignment system is shown in FIG. 5. In an active lens alignment system such as active lens alignment system 90, image sensor 14 is operational and gathers image data from a target such as target 80 that is viewed through the camera module optics such as lens 28. Control circuitry 92 adjusts the distance D between image sensor 14 and lens 28 based on information gathered by image sensor 28. Control circuitry 92 may issue control signals to computer-controlled positioner 86 and/or computer-controlled positioner 88 to adjust the distance D between image sensor 14 and lens 28. If desired, image sensor 14 may be stationary while the position of lens 28 is adjusted, or lens 28 may be stationary while the position of image sensor 14 is adjusted. The example of FIG. 5 is merely illustrative.

Control circuitry 92 may be implemented using one or more integrated circuits such as microprocessors, application specific integrated circuits, memory, and other storage and processing circuitry. Control circuitry 92 may be formed in an electronic device that is separate from image sensor 14 or may be formed in an electronic device that includes image sensor 14. If desired, some or all of control circuitry 92 may be implemented using image processing and data formatting circuitry 16 and/or storage and processing circuitry 24 of electronic device 10 (FIG. 1). This is, however, merely illustrative. If desired, control circuitry 92 may be completely separate from image sensor 14.

In addition to adjusting the position of lens 28 along the optical axis (e.g., the z-axis of FIG. 5), control circuitry 92 may also be configured to adjust the position of lens 28 along the x-axis and y-axes. If desired, control circuitry 92 may also adjust the position of lens 28 along three rotational axes (e.g., θx, θy, and θz) to achieve six degrees of freedom. In general, control circuitry 92 may be configured to more lens 28 in one two, three, four, five, or six axes.

Image sensor 14 may include phase detection pixels 100 for gathering phase information from edges 82 in target 80. Phase detection pixels 100 may, for example, include horizontal phase detection pixels 100 in region 8411 and vertical phase detection pixels 100 in region 84V. Horizontal phase detection, pixels 100 may be arranged in a line parallel to the x-axis of FIG. 5 (e.g., in one or more rows of pixel array 96) and may be used to detect vertical edges in target 80 such as vertical edges 82V. Vertical phase detection pixels 100 may be arranged in a line parallel to the y-axis of FIG. 5 (e.g., in one or more columns of pixel array 96) and may be used to detect horizontal edges in target 80 such as horizontal edge 82H.

If desired, target 80 may be designed with edges 82 in specific locations that correspond to the locations of phase detection pixels 100 in image sensor 14. In this way, only a small number of phase detection pixels 100 may be needed to achieve accurate alignment of optics 28 and image sensor 14. Cycle time may also be reduced by only reading out pixel data from phase detection pixels in pixel array 96 during active lens alignment operations. Increasing the speed of the active alignment process in this way can help reduce costs associated with the assembly process. This is, however, merely illustrative. If desired, the entire array of pixels in pixel array 96 may be read out during active alignment operations.

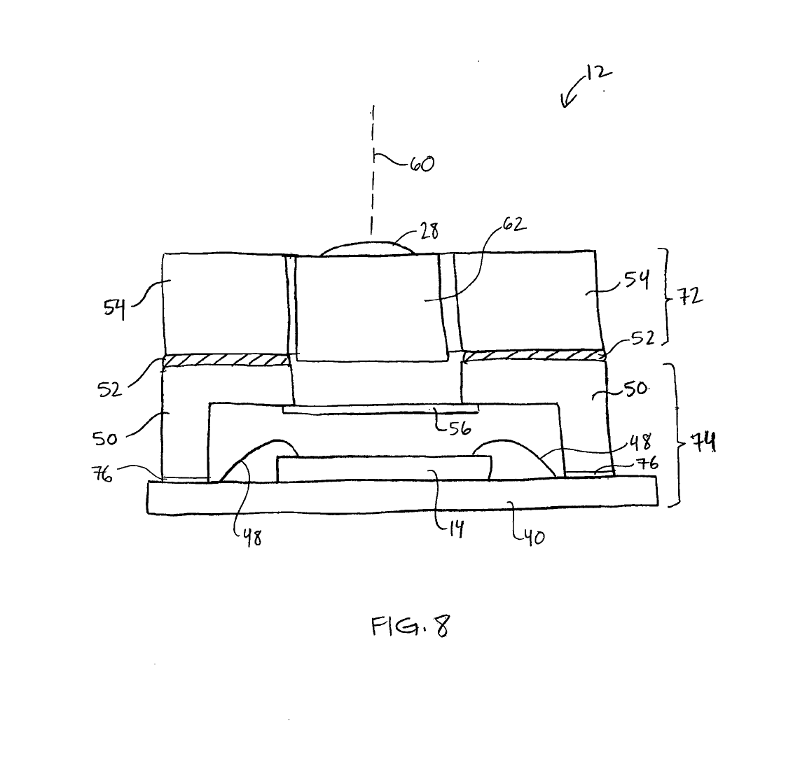

FIGS. 6, 7, 8, and 9 show illustrative examples of camera modules that may be assembled using an active alignment system of the type shown in FIG. 5.

As shown in FIG. 6, image sensor 14 of camera module 12 may be mounted to a substrate such as primed circuit substrate 40. Camera optics 28 may be arranged above image sensor 14 and may be used to focus incoming light onto image sensor 14. Camera optics 28 may include one or more lenses, one or more mirrors, one or more prisms, one or more arrays of miniature lenses, etc. Camera optics 28 may sometimes be referred to as lens 28. However, it should be understood that camera optics 28 may include one or more different types of optical structures.

Lens 28 may be supported by a lens support structure such as lens support structure 42. Lens support structure 42 may surround and enclose at least some of the internal parts of camera module 12. As shown in FIG. 6, lens support structure 42 may include opposing upper and lower surfaces such as upper surface 42U and lower surface 42L. Lens 28 may be attached to upper surface 42U using an attachment structure such as adhesive 46. Lower surface 42L of lens support structure 42 may be mounted to printed circuit board 40 using an attachment structure such as adhesive 44. The use of adhesive 46 and 44 to attach lens 2 and substrate 40 to lens support structure 42 is merely illustrative. Screws and/or other fasteners, solder, welds, clips, mounting brackets, and other structures may also be used in assembling camera module 12 if desired.

Prior to fixing the position of lens 28 relative to image sensor 14 active lens alignment operations may be performed to determine the accurate position of lens 28 relative to image sensor 14. For example, one or more attachment mechanisms in camera module 12 may remain loose during active lens alignment operations to allow for movement of lens 28 relative to image sensor 14. In the example of FIG. 6, lens support structure 42, image sensor 14, and printed circuit board 40 are fixed with respect to each other, while attachment mechanism 46 that attaches lens 28 to housing 42 is unfixed. For example, in arrangements where attachment mechanism 46 is an adhesive (e.g., a light curable adhesive such as an ultraviolet (UV) light cured polymer adhesive). the adhesive may be in an uncured state prior to and during active lens alignment operations.

As discussed in connection with FIG. 5, active lens alignment operations may involve gathering phase detection information from edges on a target using phase detection pixels in image sensor 14 and determining whether or not the edges are in focus. If the edges are not in focus, the active lens alignment system e.g., control circuitry 92) may determine the distance and direction of lens movement needed to bring the edges on the target into focus. The control circuitry may then use computer-controlled positioners positioner 86 and/or positioner 88) to adjust the position of lens 28 (e.g.. along one to six axes of motion) relative to image sensor 14 to bring the image into focus and thereby align lens 28 to image sensor 14. Once aligned, attachment structure 46 may be fastened to fix lens 28 in place (e.g., adhesive 46 may be exposed to ultraviolet light to cure adhesive 46 and thereby fix lens 28 to housing 42).

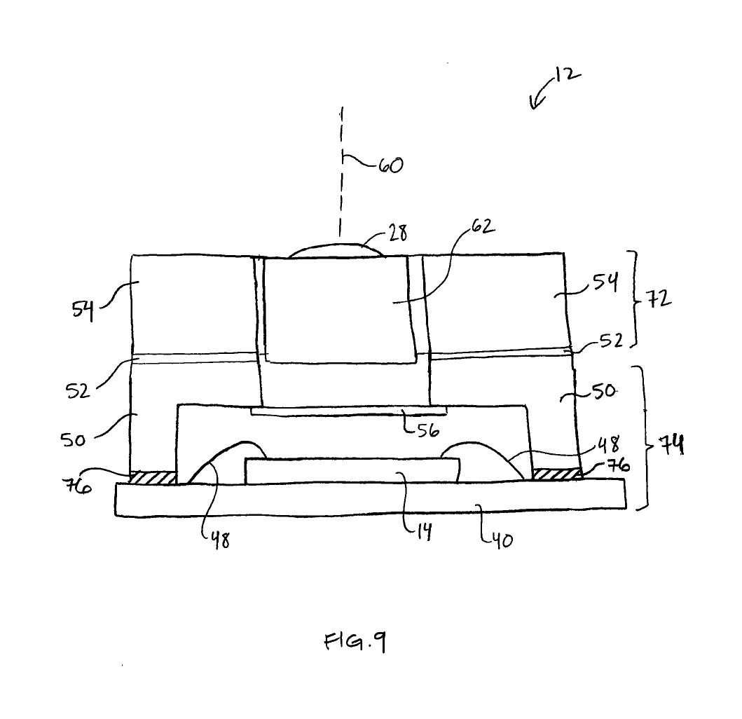

The example of FIG. 6 in which housing structure 42 and image sensor 40 are fixed relative to one another and in which lens 28 is adjusted with respect to housing structure 42 and image sensor 14 is merely illustrative. If desired, lens 28 and housing structure 42 may be fixed relative to one another and lens 28 may be adjusted with respect to substrate 40 on which image sensor 14 is mounted. This type of arrangement is shown in FIG. 7.

As shown in FIG. 7, image sensor 14 of camera module 12 may be mounted to a substrate such as printed circuit substrate 40. Lens 28 may be arranged above image sensor 14 and may be used to focus incoming light onto image sensor 14.

Lens 28 may be supported by lens support structure 42. Lens support structure 42 may surround and enclose at least some of the internal parts of camera module 12. Lens 28 may be attached to the upper surface of lens support structure 42 using an attachment structure such as adhesive 46. The lower surface of lens support structure 42 may be mounted to printed circuit board 40 using an attachment structure such as adhesive 44.

Prior to fixing the position of lens 28 relative to image sensor 14, active lens alignment operations may be performed to determine the accurate position of lens 28 relative to image sensor 14. In the example of FIG. 7, image sensor 14 and printed circuit board 40 are fixed with respect to each other, and lens 28 and support structure 42 are fixed with respect to each other (e.g., adhesive 46 is cured prior to active lens alignment operations). Attachment mechanism 44, on the other hand, remains unfixed during lens alignment to allow movement of lens 28 relative to image sensor 14. For example, in arrangements where attachment mechanism 44 is an adhesive (e.g., a light curable adhesive such as an ultraviolet (UV) light cured polymer adhesive), the adhesive may be in an uncured state prior to and during active lens alignment operations.

As discussed in connection with FIG. 5, active lens alignment operations may involve gathering phase detection information from edges on a target using phase detection pixels in image sensor 14 and determining whether or not the edges are in focus. If the edges are not in focus, the active lens alignment system (e.g., control circuitry 92) may determine the distance and direction of lens movement needed to bring the edges on the target into focus. The control circuitry may then use computer-controlled positioners (e.g., positioner 86 and/or positioner 88) to adjust the position of lens 28 (e.g., along one to six axes of motion) relative to image sensor 14 to bring the image into focus and thereby align lens 28 to image sensor 14. Once aligned, attachment structure 44 may be fastened to fix lens 28 in place (e.g., adhesive 44 may be exposed to ultraviolet tight to cute adhesive 44 and thereby fix housing 42 and lens 28 to substrate 40).

FIG. 8 is a cross-sectional side view of another suitable arrangement for camera module 12. In the example of FIG. 8, active lens alignment operations include aligning upper camera module assembly 72 to lower camera module assembly 74. Lower camera module assembly includes image sensor 14 mounted to substrate 40 and electrically coupled to circuitry on substrate 40 using wire bonds 48. If desired, other mounting techniques may be used to couple sensor 14 to substrate 40 (e.g., a ball grid array, stud bumps, etc.). The use of wire bonds 4 is merely illustrative. An enclosure such as enclosure 50 may be mounted to substrate 40 using an attachment mechanism such as adhesive 76. Enclosure 50 may at least partially enclose and surround image sensor 14 and may include an opening for allowing light to reach image sensor 14. If desired, a filter such as filter 56 may be mounted to enclosure 50 over the opening. Filter 56 may be an infrared cut-off filter that filters out all infrared light or may be a dual band-pass filter that transmits visible light and a narrow band of infrared light. If desired, filters such as filter 56 may be omitted.

Upper camera module assembly 72 may be supported by and attached to locker camera module assembly 74 using attachment mechanism 52 (e.g., a layer of adhesive, screws and/or other fasteners, solder, welds, clips, mounting brackets, etc.). Upper camera module assembly 72 includes an electromagnetically actuated focusing system 54 (e.g., an actuator such as a voice coil motor that is based on a coil of wire and permanent magnets or other electromagnetic actuator). During operation, actuator system 54 may be used to move lens carrier 62 that carries lens 28 back and forth along lens axis 60 to focus camera module 12. Actuator 54 may be based on electromagnetic structures such as wire coils (electromagnetics) and/or permanent magnets, piezoelectric actuator structures, stepper motors, shape memory metal structures, or other actuator structures. Examples of electromagnetic actuators include moving coil actuators and moving magnet actuators. Actuators that use no permanent magnets (e.g., actuators based on a pair of opposing electromagnets) may also be used.

Prior to fixing the position upper camera module assembly 72 with respect to lower camera module assembly 74, active lens alignment operations may be performed to determine the accurate position of lens 28 relative to image sensor 14. In the example of FIG. 8. the structures of upper camera module assembly 72 are fixed with respect to each other, and the structures of lower camera module assembly 74 are fixed with respect to each other prior to lens alignment. Attachment mechanism 52 that attaches upper camera module assembly 72 to lower camera module assembly 74 is unfixed during lens alignment to allow movement of lens 28 relative to image sensor 14. For example, in arrangements where attachment mechanism 52 is an adhesive (e.g., a light curable adhesive such as an ultraviolet (UV) light cured polymer adhesive), the adhesive may be in an uncured state prior to and during active lens alignment operations.

As discussed in connection with FIG. 5, active lens alignment operations may involve gathering phase detection information from edges on a target using phase detection pixels in image sensor 14 and determining whether or not the edges are in focus. If the edges are not in focus, the active lens alignment system (e.g., control circuitry 92) may determine the distance and direction of lens movement needed to bring the edges on the target into focus. The control circuitry may then use computer-controlled positioners positioner 86 and/or positioner 88) to adjust the position of lens 28 (e.g., along one to six axes of motion) relative to image sensor 14 to bring the image into focus and thereby align lens 28 to image sensor 14. Once aligned, attachment structure 52 may be fastened to fix lens 28 in place (e.g., adhesive 52 may be exposed to ultraviolet light to cure adhesive 52 and thereby fix upper camera module assembly 72 to lower camera module assembly 74).

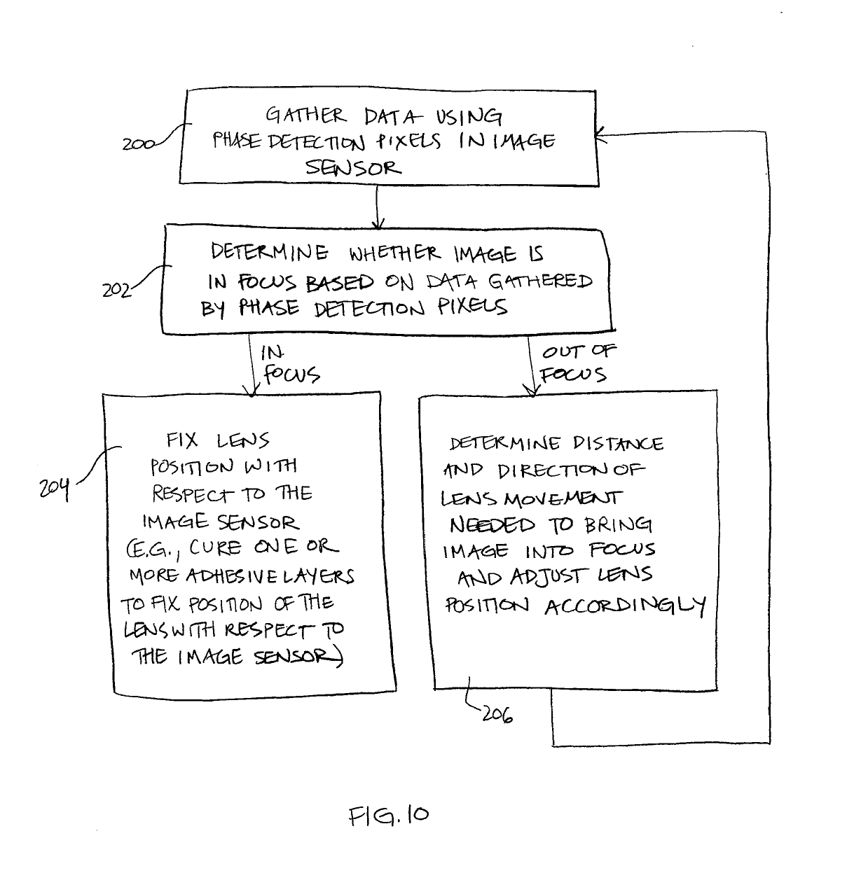

The example of FIG. 8 in which the structures of upper assembly 72 are fixed relative to one another, the structures of lower assembly 74 are fixed relative to one another, and lens 28 is adjusted with respect to enclosure 50 and image sensor 14 is merely illustrative. If desired, upper assembly 72 may be fixed relative to enclosure 50, and the position of upper assembly 72 and enclosure 50 may he adjusted with respect to substrate 40 on which image sensor 14 is mounted. This type of arrangement is shown in FIG. 9.

As shown in FIG. 9. image sensor 14 of camera module 12 may be mounted to a substrate such as printed circuit substrate 40. Lens 28 may be arranged above image sensor 14 and may be used to focus incoming light onto image sensor 14.

In the example of FIG. 9, upper camera module assembly 72 is fixed (e.g., permanently fixed) to enclosure 50 using attachment mechanism 52 (e.g., adhesive 52 has been cured to fix upper assembly 72 to enclosure 50). Prior to fixing the position upper camera module assembly 72 and enclosure 50 with respect to substrate 40, active lens alignment operations may be performed to determine the accurate position of lens 28 relative to image sensor 14. Attachment mechanism 76 that attaches enclosure 50 to substrate 40 is unfixed during lens alignment to allow movement of lens 28 relative to image sensor 14. For example, in arrangements where attachment mechanism 76 is an adhesive (e.g., a light curable adhesive such as an ultraviolet (UV) light cured polymer adhesive), the adhesive may be in an uncured state prior to and during active lens alignment operations.

As discussed in connection with FIG. 5, active lens alignment operations may involve gathering phase detection information from edges on a target using phase detection pixels in image sensor 14 and determining whether or not the edges are in focus. if the edges are not in focus, the active lens alignment system (e.g., control circuitry 92) may determine the distance and direction of lens movement needed to bring the edges on the target into focus. The control circuitry may then use computer-controlled positioners (e.g., positioner 86 and/or positioner 88) to adjust the position of lens 28 (e.g., along one to six axes of motion) relative to image sensor 14 to bring the image into focus and thereby align lens 28 to image sensor 14. Once aligned, attachment structure 76 may be fastened to fix lens 28 in place (e.g., adhesive 76 may be exposed to ultraviolet light to cure adhesive 76 and thereby fix upper camera module assembly 72 and enclosure 50 to substrate 40 on which image sensor 14 is mounted).

FIG. 10 is a flow chart of illustrative steps involved in using an active alignment system of the type shown in FIG. 5 to align camera optics to an image sensor using phase detection pixels in the image sensor.

At step 200, image sensor 14 may gather data from a target while viewing the target through camera optics 28. For example, phase detection pixels 100 in image sensor 14 may capture images of edges in the target and may produce pixel signals of the type shown in FIG. 3. Data gathered by phased detection pixels 100 may be provided to control circuitry 92 (e.g., control circuitry that is separate from camera module 12 or control circuitry that forms part of camera module 12 such as image processing circuitry 16). If desired, only the pixel output data from phase detection pixels 100 in image sensor 14 may be read out during lens alignment operations, which can significantly reduce cycle time. This is merely illustrative, however. If desired, additional pixel signals (e.g., the entire pixel array) may be read out with the phase detection pixel signals.

At step 202, control circuitry 92 may process the gathered phase information to determine whether the target is in focus. For example, control circuitry 92 may determine whether the target is in focus by comparing pixel outputs from P1 and P2 of a phase detection pixel pair such as outputs of the type shown in FIG. 3. It control circuitry 92 determines that the target image is in focus, processing may proceed to step 204.

At step 204, control circuitry 92 fixes the position of camera optics 28 relative to image sensor 14. For example, one or more adhesive layers in the camera module such as adhesive 46 of FIG. 6, adhesive 44 of FIG. 7, adhesive 52 of FIG. 8, or adhesive 76 of FIG. 9 may be exposed to ultraviolet light to cure the adhesive and lock the optics in place. The use of adhesive is merely illustrative. If desired, other attachment mechanisms may be used.

If it is determined in step 202 that the target image is not in focus, processing may proceed to step 206.

At step 206, control circuitry 92 may use the pixel output data from phase detection pixels 100 in image sensor 14 to determine the distance and direction of lens movement needed to bring the target image into focus. Control circuitry 92 may use one or more computer-controlled positioners (e.g., positioner 86 and/or positioner 88) to adjust the position of optics 28 relative to image sensor 14. This may include, for example, adjusting the position of lens 28 along the x, y, and z-axes relative to image sensor 14. The tilt of the optics may also be adjusted, if desired. In general, control circuitry 92 may adjust the position of lens 28 in one, two, three, four, five, or six axes of motion. After adjusting the position of lens 28 relative to image sensor 14, processing may proceed directly to step 204 to lock lens 28 in place or, if desired, may loop back to step 200 to verify that lens 28 is in the appropriate position.

Various embodiments have been described illustrating image sensor pixel arrays having image pixels for capturing image data and phase detection pixels for gathering phase information. The phase detection pixels may be used for active lens alignment during camera module assembly operations. The phase detection pixels may also be used during image capture operations to provide automatic focusing and depth sensing functionality.

In an active lens alignment system, the image sensor is operational and gathers image data from a target image that is viewed through the camera module optics. Control circuitry in the active lens alignment system may use one or more computer-controlled positioners to adjust the position of camera module optics relative to the image sensor before permanently attaching structures in camera module assembly.

The image sensor may gather data from a target using phase detection pixels in the image sensor. The control circuitry may process the phase detection pixel data to determine whether the target image is in focus. If the target image is not in focus, the control circuitry may determine the distance and direction of lens movement needed to bring the target image into focus and may move the lens accordingly using the computer-controlled positioners.

In response to determining that the lens is properly aligned with the image sensor, the alignment may be locked in place. This may include curing one or more layers of adhesive in the camera module, tightening one or more screws in the camera module, fastening one or more fasteners in the camera module, etc.

If desired, the phase detection pixels may be used during image capture operations (e.g., during automatic focusing operations and/or for other applications). Processing circuitry in the imaging system may replace phase detection pixel values with interpolated image pixel values during an image reconstruction process.

The foregoing is merely illustrative of the principles of this invention and various modifications can he made by those skilled in the art without departing from the scope and spirit of the invention.

What is claimed is:

1. A method for aligning an optical element with respect to an image sensor during assembly of a camera module, wherein the image sensor comprises a pixel array having image pixels and at least one pair of phase detection pixels, wherein the pair of phase detection pixels includes a first pixel and a second pixel having different angular responses, the method comprising:
with the pair of phase detection pixels, viewing a target through the optical element and gathering data from the target; and
with control circuitry, adjusting a position of the optical element relative to the image sensor based on the gathered data to align the optical element with respect to the image sensor.

2. The method defined in claim 1 further comprising:
after adjusting the position of the optical element relative to the image sensor, fixing the position of the optical element relative to the image sensor.

3. The method defined in claim 2 wherein fixing the position of the optical element relative to the image sensor comprises curing a layer of adhesive in the camera module.

4. The method defined in claim 3 wherein the camera module comprises a lens support structure, wherein the optical element comprises a lens, and wherein curing the layer of adhesive in the camera module comprises curing a layer of adhesive interposed between the lens and the lens support structure to permanently attach the lens to the lens support structure.

5. The method defined in claim 3 wherein the camera module comprises a substrate on which the image sensor is mounted and an enclosure that at least partially encloses the image sensor, and wherein curing the layer of adhesive in the camera module comprises curing a layer of adhesive interposed between the enclosure and the substrate to permanently attach the enclosure to the substrate.

6. The method defined in claim 3 wherein the camera module comprises an upper assembly having a voice coil motor and a lower assembly having a substrate, wherein the optical element is formed in the upper assembly, wherein the image sensor is formed in the lower assembly, and wherein curing the layer of adhesive in the camera module comprises curing a layer of adhesive interposed between the upper assembly and the lower assembly to permanently attach the upper assembly the lower assembly.

7. The method defined in claim 1 wherein the at least one pair of phase detection pixels comprises a first plurality of phase detection pixels arranged in a row in the pixel array and a second plurality of phase detection pixels arranged in a column in the pixel array.

8. The method defined in claim 7 wherein gathering data with the at least one pair of phase detection pixels comprises:
with the first plurality of phase detection pixels, detecting a vertical edge in the target; and
with the second plurality of phase detection pixels, detecting a horizontal edge in the target.

9. The method defined in claim 8 wherein adjusting the position of the lens based on the gathered data comprises:
adjusting the position of the optical element along a first axis based on information from the first plurality of phase detection pixels; and
adjusting the position of the optical element along a second axis based on information from the second plurality of phase detection pixels.

10. The method defined in claim I wherein adjusting the position of the optical element comprises:
with the control circuitry, operating a computer-controlled positioner to adjust the position of the optical element with respect to the image sensor.

11. A method for aligning a lens with respect to an image sensor during assembly of a camera module wherein the image sensor comprises image pixels and phase detection pixels and wherein the phase detection pixels have asymmetric angular responses, the method comprising:
with readout circuitry in the image sensor, reading out phase detection pixel signals from the phase detection pixels; and
with a computer-controlled positioner, adjusting a position of the lens relative to the image sensor based on the phase detection pixel signals.

12. The method defined in claim 11 further comprising:
after adjusting the position of the lens relative to the image sensor, fixing the position of the lens relative to the image sensor.

13. The method defined in claim 12 wherein fixing the position of the lens relative to the image sensor comprises curing a layer of adhesive in the camera module.

14. The method defined in claim 11 wherein reading out the phase detection, pixels comprises reading out phase detection pixel signals without reading out any image pixel signals from the image pixels.

15. The method defined in claim 11 wherein adjusting the position of the lens relative to the image sensor comprises adjusting a tilt of the lens relative to the image sensor.

16. A lens alignment system for aligning camera module structures during assembly of a camera module, comprising:
an image sensor having image pixels and phase detection pixels, wherein the phase detection pixels have asymmetric angular responses;
a lens arranged in front of the image sensor;
a target arranged in front of the image sensor, wherein the image
sensor views the target through the lens and wherein the phase detection pixels gather phase information from the target; and
a computer-controlled positioner that adjusts a position of the lens relative to the image sensor based on the phase information.

17. The lens alignment system defined in claim 16 wherein the target comprises edges in locations that correspond to locations of the phase detection pixels in the image sensor.

18. The lens alignment system defined in claim 16 further comprising:
control circuitry that receives the phase information and that determines a distance and direction of lens movement needed to bring the target into focus.

19. The lens alignment system defined in claim 18 wherein the control circuitry issues control signals to the computer-controlled positioner to adjust the position of the lens based on the distance and direction of lens movement needed to bring the target into focus.

20. The lens alignment system defined in claim 16 wherein the phase detection pixels comprise a first plurality of phase detection pixels arranged in a first line and a second plurality of phase detection pixels arranged in a second line, wherein the first line is perpendicular to the second line, wherein the first plurality of phase detection pixels detect horizontal edges in the target, and wherein the second plurality of phase detection pixels detect vertical edges in the target.
